(19) United States
(12) Patent Application Publication
(10) Pub. No.: US 2020/0328142 A1
(43) Pub. Date: Oct. 15, 2020

(54) PACKAGE STACK STRUCTURE, METHOD FOR FABRICATING THE SAME, AND CARRIER COMPONENT

(71) Applicant: Siliconware Precision Industries Co., Ltd., Taichung (TW)

(72) Inventors: Don-Son Jiang, Taichung (TW); Nai-Hao Kao, Taichung (TW); Chih-Sheng Lin, Taichung (TW); Szu-Hsien Chen, Taichung (TW); Chih-Yuan Shih, Taichung (TW); Chia-Cheng Chen, Taichung (TW); Yu-Cheng Pai, Taichung (TW); Hsuan-Hao Mi, Taichung (TW)

(21) Appl. No.: 16/538,286

(22) Filed: Aug. 12, 2019

(30) Foreign Application Priority Data
Apr. 9, 2019 (TW) 108112327
May 8, 2019 (TW) 108115893

(51) Int. Cl. H01L 23/498; H01L 23/14; H01L 23/367; H01L 23/00; H01L 21/48

(52) U.S. Cl. CPC H01L 23/49833; H01L 2924/3511; H01L 23/145; H01L 23/3675; H01L 23/49816; H01L 24/81; H01L 24/16; H01L 21/4853; H01L 21/4857; H01L 24/32; H01L 24/73; H01L 24/33; H01L 24/83; H01L 24/92; H01L 2224/16227; H01L 2224/32225; H01L 2224/32245; H01L 2224/33181; H01L 2224/73204; H01L 2224/73253; H01L 23/49822

(57) ABSTRACT

A package stack structure and a method for fabricating the same are provided. An electronic component is disposed on the topmost one of a plurality of organic material substrates, and no chip is disposed on the remaining organic material substrates. A predefined layer number of circuit layers are disposed in the organic material substrates, and distributes the thermal stress via the organic material substrates. Therefore, the bottommost one of the organic material substrates will not be separated from a circuit board due to CTE mismatch. Also a carrier component is provided.

### CROSS-REFERENCE TO RELATED APPLICATIONS

This application claims priority to Taiwanese Application Serial No. 108112327, filed on Apr. 9, 2019, and Taiwanese Application Serial No. 108115893, filed on May 8, 2019. The entirety of the applications is hereby incorporated by reference herein and made a part of this specification.

### BACKGROUND

### 1. Technical Field

The present disclosure relates to packaging processes, and, more particularly, to a package stack structure, a method for fabricating the same, and a carrier component.

### 2. Description of the Prior Art

With the rapid development of portable electronic products in recent years, various corresponding products have gradually developed towards high density, high performance, compact size and low profile.

FIG. 1 is a schematic diagram of an electronic device 1 according to the prior art. The electronic device 1 comprises a mother board 1b, such as a circuit board, and an electronic package 1a mounted onto the mother board 1b. The electronic package 1a comprises a packaging substrate 11, a semiconductor chip 10 bonded via a plurality of conductive bumps 100 to the packaging substrate 11 in a flip-chip manner, and an underfill 12 that fixes the semiconductor chip 10 and encapsulates the conductive bumps 100. The packaging substrate 11 of the electronic package 1a is mounted via a plurality of solder balls 13 onto the mother board 1b.

In the development of semiconductor technology, the semiconductor chip 10 (or the electronic package la) is becoming larger and larger in a flip-chip packaging process, and a die corner stress occurring in the semiconductor chip 10 due to stress concentration at corners after the package of the semiconductor chip 10 is becoming higher and higher. As a result, a great stress is generated between the semiconductor chip 10 and the underfill 12, as indicated by a dashed circle shown in FIG. 1, which causes the cracking of the semiconductor chip 10 along its corners. To address the problem, an insulation substrate of an ultra low coefficient of thermal expansion (CTE) is used as a board of the packaging substrate 11, such as a copper clad laminate (CCL), an Ajinomoto build-up film (ABF), a prepreg (PP), a solder mask (SM), etc., to try to reduce the die corner stress.

In the electronic device 1 according to the prior art, the CTE of the mother board 1b does not become smaller accordingly with the packaging substrate 11, which causes the packaging substrate 11 to be separated from the mother board 1b due to CTE mismatch. Therefore, the solder balls 13 have poor connection reliability, the packaging substrate 11 cannot be electrically connected to the mother board 1b effectively (e.g., open circuit) or cannot pass the reliability test (e.g., not connected completely), and the product thus fabricated has a poor yield.

The packaging substrate 11 is becoming larger and larger and has more and more layers as a number of chips disposed thereon increases. Therefore, the packaging substrate 11 is not likely to have a satisfied fabrication yield (i.e., the more the layers are, the greater the error becomes), and has a high cost. For example, if the packaging substrate 11 has ten circuit layers, and each of circuit layers has a fabrication yield of 95%, the packaging substrate 11 of ten circuit layers will have a yield as low as 59.8% (i.e., 0.95¹⁰). Therefore, it is hard to fabricate the packaging substrate 11 in current fabrication processes. The current fabrication processes must be re-planned, which increases the fabrication complexity.

Therefore, how to overcome the problems of the prior art is becoming an urgent issue in the art.

### SUMMARY

In view of the problems of the prior art, the present disclosure provides a package stack structure, comprising: a carrier component including: a plurality of circuit layers; a first organic material substrate having a first circuit portion; and at least one second organic material substrate having a second circuit portion, the first organic material substrate being stacked on the second organic material substrate via a plurality of supporting bodies; and at least one electronic component disposed on the first organic material substrate and electrically connected to the plurality of circuit layers, wherein a layer number of the plurality of circuit layers to be electrically connected to the electronic component is distributed in the first circuit portion and the second circuit portion.

The present disclosure further provides a method for fabricating a package stack structure, comprising: providing a first organic material substrate having a first circuit portion and at least one second organic material substrate having a second circuit portion; disposing at least one electronic component on the first organic material substrate; and stacking the first organic material substrate via a plurality of supporting bodies on the second organic material substrate to constitute a carrier component having a plurality of circuit layers, and electrically connecting the electronic component to the plurality of circuit layers, wherein a layer number of the plurality of circuit layers to be electrically connected to the electronic component is distributed in the first circuit portion and the second circuit portion.

In an embodiment, the first circuit portion and the second circuit portion have different layer numbers of circuit layers.

In an embodiment, the first circuit portion and the second circuit portion have the same layer number of circuit layers.

In an embodiment, a heat dissipater is further disposed on the first organic material substrate.

In an embodiment, the first organic material substrate is stacked with the plurality of second organic material substrates, and the second organic material substrates are stacked with each other via a plurality of supporting members.

In an embodiment, the supporting bodies are electrically connected to the first organic material substrate and the second organic material substrate.

In an embodiment, the second organic material substrate is further stacked via a plurality of conductive elements on a circuit board. In another embodiment, the conductive elements are electrically connected to the circuit board and the second organic material substrate, and the second organic material substrate has a coefficient of thermal expansion between a coefficient of thermal expansion of the circuit board and a coefficient of thermal expansion of the first organic material substrate. In another embodiment, the second organic material substrate and the circuit board have different coefficients of thermal expansion.

In an embodiment, the first organic material substrate and the second organic material substrate have different coefficients of thermal expansion.

The present disclosure further provides a carrier component, comprising: a plurality of circuit layers; a first organic material substrate having a first circuit portion; and a second organic material substrate having a second circuit portion, the first organic material substrate being stacked on the second organic material substrate via a plurality of supporting bodies, wherein a layer number of the plurality of circuit layers is distributed in the first circuit portion and the second circuit portion.

In an embodiment, the first circuit portion and the second circuit portion have different layer numbers of circuit layers.

In an embodiment, the first circuit portion and the second circuit portion have the same layer number of circuit layers.

In an embodiment, the first organic material substrate is stacked with the plurality of second organic material substrates, and the second organic material substrates are stacked with each other via a plurality of supporting members. In another embodiment, the carrier component further comprises an encapsulation layer formed between the second organic material substrates and encapsulating the plurality of supporting members.

In an embodiment, the supporting bodies are electrically connected to the first organic material substrate and the second organic material substrates.

In an embodiment, the first organic material substrate and the second organic material substrate have different coefficients of thermal expansion.

In an embodiment, the carrier component further comprises an encapsulation layer that encapsulates the plurality of supporting bodies.

In the package stack structure, the method for fabricating the same and the carrier component according to the present disclosure, a predefined layer number of circuit layers are disposed in the first and second organic material substrates. Compared with the prior art, the present disclosure can distribute the thermal stress via the second organic material substrate and avoid the first organic material substrate and the circuit board from being separated due to CTE mismatch. Therefore, the second organic material substrate can be electrically connected to the circuit board or pass the reliability test, and the yield of the product thus fabricated is increased.

Even if there are many circuit layers, a predefined layer number of circuit layers can still be disposed in the first and second organic material substrates, so as to increase the fabrication yield and reduce the fabrication cost effectively.

Due to the difference of CTEs of the first and second organic material substrates, the CTE of the package stack structure can change gradually, and the package stack structure can be prevented from warpage due to mass changing of a thermal stress.

### BRIEF DESCRIPTION OF THE DRAWINGS

The disclosure can be more fully understood by reading the following detailed description of the embodiments, with reference made to the accompanying drawings, wherein:

FIG. 1 is a cross-sectional view of an electronic device according to the prior art;

FIGS. 2A to 2E are cross-sectional views illustrating a method for fabricating a package stack structure according of an embodiment to the present disclosure;

FIG. 3 is a cross-sectional view of a package stack structure of another embodiment according to the present disclosure; and

FIGS. 4A and 4B are cross-sectional views of different embodiments of a carrier component according to the present disclosure.

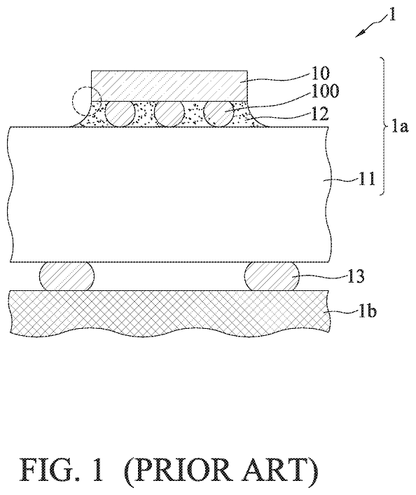

### DETAILED DESCRIPTION

The following illustrative embodiments are provided to illustrate the disclosure of the present disclosure, these and other advantages and effects can be apparently understood by those in the art after reading the disclosure of this specification.

It should be appreciated that the structures, proportions, size and the like of the figures in the present application are intended to be used in conjunction with the disclosure of the specification. They are not intended to limit the disclosure and therefore do not represent any substantial technical meanings. The details of the specification may be on the basis of different points and applications, and numerous modifications and variations can be devised without departing from the spirit of the present disclosure. As used herein, the terms “first,” “second,” “a” and the like, are used to distinguish one element from another, and are not intended to limit the scope of the present application. Changes or adjustments are considered to be within the scope of the present disclosure, without departing from the scope of the present disclosure.

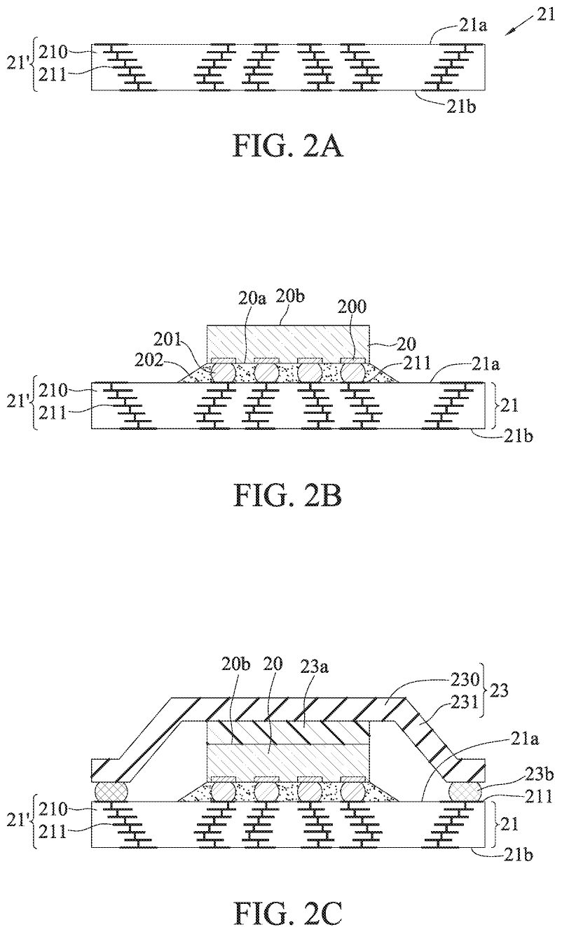

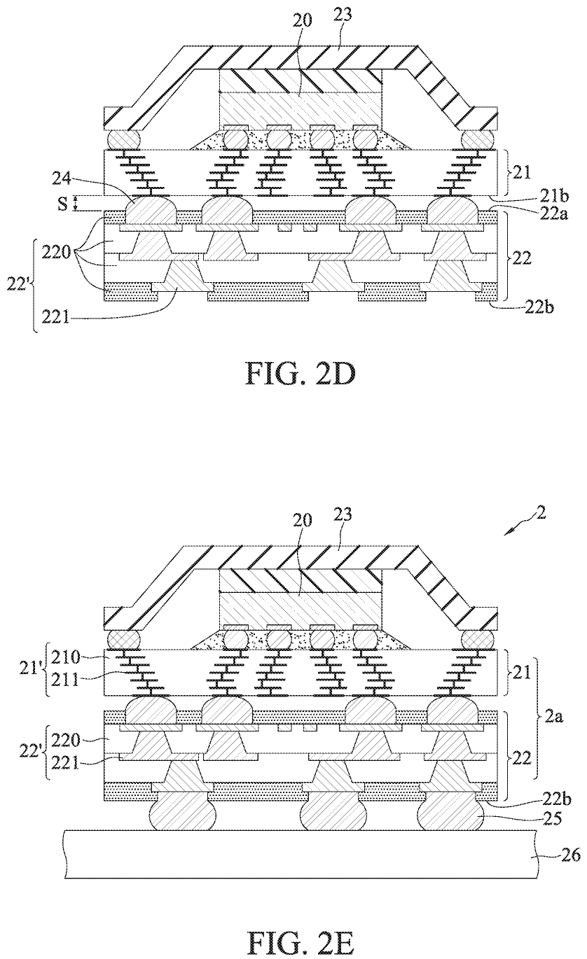

FIGS. 2A to 2E are cross-sectional views illustrating a method for fabricating a package stack structure 2 according to an embodiment of the present disclosure.

As shown in FIG. 2A, a first organic material substrate 21 having a first circuit portion 21′ is provided.

In an embodiment, the first organic material substrate 21 is a circuit structure having a core layer or a coreless circuit structure, such as a packaging substrate, which is defined with a first surface 21a and a second surface 21b opposing the first surface 21a. The first circuit portion 21′ includes at least one first insulation layer 210 and a first circuit layer 211 formed on the first insulation layer 210. In an embodiment, the fan out first circuit layer 211 is formed in a redistribution layer (RDL) manner, and is formed of copper. In another embodiment, the first insulation layer 210 is formed of a dielectric layer, such as polybenzoxazole (PBO), polyimide (PI) and prepreg (PP), or a solder mask, such as solder resist and graphite.

As shown in FIG. 2B, at least one electronic component 20 is disposed on the first organic material substrate 21 and electrically connected to the first circuit layer 211 of the first circuit portion 21′.

In an embodiment, the electronic component 20 is a package, such as a chip scale package (CSP), an active element, such as a semiconductor chip, a passive element, such as a resistor, a capacitor and an inductor, or a combination thereof. In an embodiment, the electronic component 20 is an active element, and has an active surface 20a and an inactive surface 20b opposing the active surface 20a. The active surface 20a has a plurality of electrode pads 200 that are disposed via a plurality of conductive bumps 201, such as a solder tin material, on the first surface 21a of the first organic material substrate 21 in a flip-chip manner and electrically connected to the first circuit layer 211. An underfill 202 encapsulates the conductive bumps 201. In another embodiment, the electronic component 20 is disposed through its inactive surface 20b on the first surface 21a of the first organic material substrate 21, and the electrode pads 200 are electrically connected to the first circuit layer 211 by a plurality of solder wires (not shown) in a wire bonding manner. In another embodiment, the electronic component 20 is in direct contact with the first circuit layer 211 and electrically connected to the first circuit layer 211. The electronic component 20 can be electrically connected to the first organic material substrate 21 in other manners.

The electronic component 20 can be disposed on the second surface 21b of the first organic material substrate 21 or other places.

As shown in FIG. 2C, a heat dissipater 23 can be disposed on the first surface 21a of the first organic material substrate 21 optionally.

In an embodiment, the heat dissipater 23 is made of metal, comprises a piece portion 230 and a leg portion 231, and is bonded through its piece portion 230 to the inactive surface 20b of the electronic component 20 via a bonding layer 23a. The leg portion 231 of the heat dissipater 23 is installed on the first surface 21a of the first organic material substrate 21 (or the first circuit layer 211) via an adhesive layer 23b. In an embodiment, the bonding layer 23a is made of a thermal interface material (TIM), heat conducting resin, or other suitable materials, and the adhesive layer 23b is insulation resin, conductive resin, or other suitable materials.

As shown in FIG. 2D, the first organic material substrate 21 is stacked via a plurality of supporting bodies 24 on at least one second organic material substrate 22 having a second circuit portion 22′, no chip is disposed on the second organic material substrate 22, and a space S is formed between the first organic material substrate 21 and the second organic material substrate 22.

In an embodiment, the second organic material substrate 22 is a circuit structure having a core layer or a coreless circuit structure, such as a packaging substrate, which is defined with a first side 22a and a second side 22b opposing the first side 22a. The first organic material substrate 21 is stacked through its second surface 21b on the first side 22a of the second organic material substrate 22. The second circuit portion 22′ comprises at least one second insulation layer 220 and a second circuit layer 221 formed on the second insulation layer 220. In an embodiment, the fan out second circuit layer 221 is formed in a redistribution layer (RDL) manner, and is made of copper. In another embodiment, the second insulation layer 220 is formed of a dielectric layer, such as polybenzoxazole (PBO), polyimide (PI) and prepreg (PP), or a solder mask, such as solder resist and graphite.

In an embodiment, the first organic material substrate 21 and the second organic material substrate 22 have different CTEs. In an embodiment, the first circuit layer 211 of the first circuit portion 21′ and the second circuit layer 221 of the second circuit portion 22′ have the same layer number, the first insulation layer 210 and the second insulation layer 220 are made of different materials, and the first organic material substrate 21 and the second organic material substrate 22 have different CTEs.

In another embodiment, the first insulation layer 210 and the second insulation layer 220 are made of the same material, the first circuit layer 211 of the first circuit portion 21′ (or the first insulation layer 210) and the second circuit layer 221 of the second circuit portion 22′ (or the second insulation layer 220) have different layer numbers, and the first organic material substrate 21 and the second organic material substrate 22 have different CTEs.

In an embodiment, the supporting bodies 24 are solder balls, copper core balls, or a metal member (in the shape of a pillar, a block or a needle) made of copper or gold, and are electrically connected to the first organic material substrate 21 and the second organic material substrate 22.

As shown in FIG. 2E, the second organic material substrate 22 is disposed through its second side 22b on a circuit board 26 via a plurality of conductive elements 25.

In an embodiment, the insulation board of the circuit board 26 is made of different material from the first insulation layer 210 and the second insulation layer 220, and the second organic material substrate 22 has CTE different from (e.g., less than) the CTE of the circuit board 26.

In an embodiment, the conductive elements 25 are solder balls, copper core balls, or a metal member (in the shape of a pillar, a block or a needle) made of copper or gold, and are electrically connected to the circuit board 26 and the second organic material substrate 22.

In the method according to the present disclosure, a predefined layer number of circuit layers are disposed in the first organic material substrate 21 and the second organic material substrate 22, respectively. The first organic material substrate 21 and the second organic material substrate 22 are assembled (e.g., stacking) to constitute the carrier component 2a having a needed number of circuit layers, and the first organic material substrate 21 and the second organic material substrate 22 have different CTEs. Compared with the prior art, the method according to the present disclosure, under a condition that the CTE of the circuit board 26 is constant, can use the second organic material substrate 22 to buffer the overall thermal expansion deformation of the carrier component 2a, prevent the carrier component 2a and the circuit board 26 from being separated due to the CTE mismatch, and solve the problem of the connection reliability of the conductive elements 25. Therefore, the second organic material substrate 22 can be electrically connected to the circuit board 26 effectively, or the carrier component 2a can pass the reliability test, to increase the yield of the product thus fabricated.

Even if the carrier component 2a is becoming larger and larger and needs more circuit layers, a predefined layer number of circuit layers (the first circuit layers 211 and the second circuit layers 221) can still be disposed in the first organic material substrate and the second organic material substrate 22, to increase the fabrication yield of the carrier component 2a and reduce the fabrication cost of the carrier component 2a.

In an embodiment, carrier component 2a has ten circuit layers, seven of which (the first circuit layer 211) are disposed in the first organic material substrate 21 and three of which (the second circuit layers 221) are disposed in the second organic material substrate 22. If each of the circuit layers has a fabrication yield of 95%, the yield of the first organic material substrate 21 is 68.8% (i.e., 0.95⁷), and the yield of the second organic material substrate 22 is 85.7% (i.e., 0.95³). Therefore, the carrier component 2a can be fabricated by the current fabrication process, and the fabrication cost will be greatly reduced.

In another embodiment, six first circuit layers 211 are disposed in the first organic material substrate 21, and four second circuit layers 221 are disposed in the second organic material substrate 22. In yet another embodiment, five first circuit layers 211 are disposed in the first organic material substrate 21, and five second circuit layers 221 are disposed in the second organic material substrate 22. Therefore, any layer number of circuit layers can be disposed in the first organic material substrate 21 and the second organic material substrate 22 on demands.

In the package stack structure 2, the board structures are arranged based on their CTEs. In an embodiment, from top to bottom are arranged with the first organic material substrate 21 (having the least CTE), the second organic material substrate 22 (having a CTE between the CTE of the first organic material substrate and the CTE of the circuit board) and the circuit board 26 (having the greatest CTE). Therefore, the CTEs change gradually from top to bottom, and the warpage problem due to mass changing of a thermal stress can be solved.

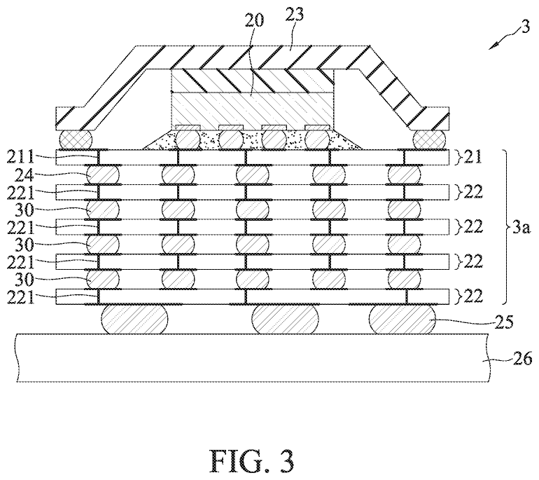

In another embodiment, such as a package stack structure 3 shown in FIG. 3, to meet the yield demand, the carrier component 3a can comprise a plurality of second organic material substrates 22, which are stacked via a plurality of supporting members 30. In an embodiment, the second organic material substrates 22 have the same or different CTEs. In an embodiment, the supporting members 30 are solder balls, copper core balls, or a metal member (in the shape of a pillar, a block or a needle) made of copper or gold, and are electrically connected to the circuit board 26 and the second organic material substrates 22. In an embodiment, the second organic material substrates 22 have different CTEs, the CTEs of the second organic material substrates 22 increase gradually from the first organic material substrate 21 to the circuit board 26.

In an embodiment, the carrier component 3a has ten circuit layers, two of which (the first circuit layers 211) are disposed in the first organic material substrate 21, and two of which (the second circuit layers 221) are disposed in each of the four second organic material substrates 22. If the fabrication yield of each of the circuit layers is 95%, the yield of the first organic material substrate 21 is 90.3% (i.e., 0.95²), and the yield of each of the second organic material substrates 22 is 90.3% (i.e., 0.95²). Therefore, the carrier component 3a can be fabricated by the current fabrication process, and the fabrication cost is greatly reduced.

The present disclosure further provides a package stack structure 2, 3, comprising: a first organic material substrate 21, at least one electronic component 20 and at least one second organic material substrate 22.

The first organic material substrate 21 has a first circuit portion 21′. The electronic component 20 is disposed on the first organic material substrate 21 and electrically connected to the first circuit portion 21′.

The second organic material substrate 22 has a second circuit portion 22′, the first organic material substrate 21 is stacked on the second organic material substrate 22 via a plurality of supporting bodies 24, and no chip is disposed on the second organic material substrate 22.

In an embodiment, the first circuit portion 21′ and the second circuit portion 22′ have different layer numbers of circuit layers.

In an embodiment, the first circuit portion 21′ and the second circuit portion 22′ have the same layer number of circuit layers.

In an embodiment, a heat dissipater 23 is disposed on the first organic material substrate 21.

In an embodiment, the first organic material substrate 21 is stacked with a plurality of the second organic material substrates 22, and the second organic material substrates 22 are stacked with each other via a plurality of supporting members 30.

In an embodiment, the supporting bodies 24 are electrically connected to the first organic material substrate 21 and the second organic material substrate 22.

In an embodiment, the package stack structure 2, 3 further comprises a circuit board 26, and the second organic material substrate 22 is stacked via a plurality of conductive elements 25 on the circuit board 26. In an embodiment, the conductive elements 25 are electrically connected to the circuit board 26 and the second organic material substrate 22. In another embodiment, the second organic material substrate 22 and the circuit board 26 have different CTEs.

In an embodiment, the first organic material substrate 21 and the second organic material substrate 22 have different CTEs.

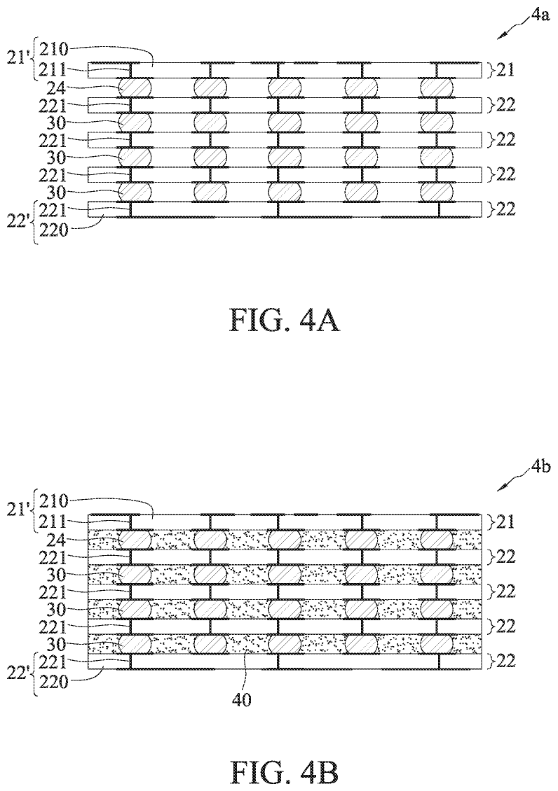

Refer to FIGS. 4A and 4B. The present disclosure also provides a carrier component 2a, 3a, 4a, 4b, which is arranged with a plurality of circuit layers and comprises at least one first organic material substrate 21 and at least one second organic material substrate 22.

The first organic material substrate 21 has a first circuit portion 21′.

The second organic material substrate 22 has a second circuit portion 22′. The first organic material substrate 21 is stacked via a plurality of supporting bodies 24 on the second organic material substrate 22. A layer number of the plurality of circuit layers of the carrier component 2a, 3a, 4a, 4b is distributed in the first circuit portion 21′ and the second circuit portion 22′.

In an embodiment, the first circuit portion 21′ and the second circuit portion 22′ have different layer numbers of circuit layers.

In an embodiment, the first circuit portion 21′ and the second circuit portion 22′ have the same layer number of circuit layers.

In an embodiment, the first organic material substrate 21 is stacked with a plurality of the second organic material substrate 22, and the second organic material substrates 22 are stacked with each other via a plurality of supporting members 30. In another embodiment, the carrier component 4b further comprises an encapsulation layer 40 formed between the second organic material substrates 22 and encapsulates the plurality of supporting members 30. In an embodiment, the encapsulation layer 40 is an insulation material, such as encapsulant or molding compound of polyimide (PI), a dry film or epoxy.

In an embodiment, the supporting bodies 24 are electrically connected to the first organic material substrate 21 and second organic material substrate 22.

In an embodiment, the first organic material substrate 21 and the second organic material substrate 22 have different coefficients of thermal expansion.

In an embodiment, the carrier component 4b further comprises an encapsulation layer 40 that encapsulates the plurality of supporting bodies 24. In an embodiment, the encapsulation layer 40 is an insulation material, such as encapsulant or molding compound of polyimide (PI), a dry film of epoxy.

In a package stack structure, a method for fabricating the same, and a carrier component according to the present disclosure, a predefined layer number of circuit layers are disposed in the first and second organic material substrates, and the first and second organic material substrates have different CTEs. Therefore, the present disclosure can use the second organic material substrate to distribute the thermal stress, to avoid the first organic material substrate and the circuit board from being separated due to the CTE mismatch. Therefore, the second organic material substrate can be electrically connected to the circuit board effectively, or the first and second organic material substrates can pass the reliability test, to increase the yield of the product thus fabricated.

Even if more circuit layers are needed, a predefined layer number of the circuit layers can be disposed in a plurality of second organic material substrates, to increase the fabrication yield of the organic material substrates and reduce the fabrication cost of the organic material substrates effectively.

In the package stack structure according to the present disclosure, the organic material substrate and the circuit board are arranged in an order based on their CTEs, to solve the warpage problem due to mass changing of the thermal stress.

The foregoing descriptions of the detailed embodiments are only illustrated to disclose the features and functions of the present disclosure and not restrictive of the scope of the present disclosure. It should be understood to those in the art that all modifications and variations according to the spirit and principle in the disclosure of the present disclosure should fall within the scope of the appended claims.

What is claimed is:

1. A carrier component, comprising:
a plurality of circuit layers;
a first organic material substrate having a first circuit portion; and
at least one second organic material substrate having a second circuit portion, the first organic material substrate being stacked on the second organic material substrate via a plurality of supporting bodies,
wherein a layer number of the plurality of circuit layers is distributed in the first circuit portion and the second circuit portion.

2. The carrier component of claim 1, wherein the first circuit portion and the second circuit portion have different layer numbers of circuit layers.

3. The carrier component of claim 1, wherein the first circuit portion and the second circuit portion have the same layer number of circuit layers.

4. The carrier component of claim 1, wherein the first organic material substrate is stacked with a plurality of the second organic material substrates, and the second organic material substrates are stacked with each other via a plurality of supporting members.

5. The carrier component of claim 4, further comprising an encapsulation layer formed between the second organic material substrates and encapsulating the plurality of supporting members.

6. The carrier component of claim 1, wherein the supporting bodies are electrically connected to the first organic material substrate and the second organic material substrate.

7. The carrier component of claim 1, wherein the first organic material substrate and the second organic material substrate have different coefficients of thermal expansion.

8. The carrier component of claim 1, further comprising an encapsulation layer encapsulating the plurality of supporting bodies.

9. A package stack structure, comprising:
the carrier component of claim 1; and
at least one electronic component disposed on the first organic material substrate and electrically connected to the plurality of circuit layers,
wherein the layer number of the plurality of circuit layers is electrically connected to the electronic component.

10. The package stack structure of claim 9, further comprising a heat dissipater disposed on the first organic material substrate.

11. The package stack structure of claim 9, further comprising a circuit board, wherein the second organic material substrate is stacked via a plurality of conductive elements on the circuit board.

12. The package stack structure of claim 11, wherein the conductive elements are electrically connected to the circuit board and the second organic material substrate.

13. The package stack structure of claim 11, wherein the second organic material substrate and the circuit board have different coefficients of thermal expansion, and the second organic material substrate has a coefficient of thermal expansion between a coefficient of thermal expansion of the circuit board and a coefficient of thermal expansion of the first organic material substrate.

14. A method for fabricating a package stack structure, comprising:
providing a first organic material substrate having a first circuit portion and at least one second organic material substrate having a second circuit portion;
disposing at least one electronic component on the first organic material substrate; and
stacking the first organic material substrate via a plurality of supporting bodies on the second organic material substrate to constitute a carrier component having a plurality of circuit layers, and electrically connecting the electronic component to the plurality of circuit layers,
wherein a layer number of the plurality of circuit layers to be electrically connected to the electronic component is distributed in the first circuit portion and the second circuit portion.

15. The method of claim 14, wherein the first circuit portion and the second circuit portion have different layer numbers of circuit layers.

16. The method of claim 14, wherein the first circuit portion and the second circuit portion have the same layer number of circuit layers.

17. The method of claim 14, further comprising disposing a heat dissipater on the first organic material substrate.

18. The method of claim 14, wherein the first organic material substrate is stacked with a plurality of the second organic material substrates, and the second organic material substrates are stacked with each other via a plurality of supporting members.

19. The method of claim 14, wherein the supporting bodies are electrically connected to the first organic material substrate and the second organic material substrate.

20. The method of claim 14, further comprising stacking the second organic material substrate via a plurality of conductive elements on a circuit board.

21. The method of claim 20, wherein the conductive elements are electrically connected to the circuit board and the second organic material substrate.

22. The method of claim 20, wherein the second organic material substrate and the circuit board have different coefficients of thermal expansion, and the second organic material substrate has a coefficient of thermal expansion between a coefficient of thermal expansion of the circuit board and a coefficient of thermal expansion of the first organic material substrate.

23. The method of claim 14, wherein the first organic material substrate and the second organic material substrate have different coefficients of thermal expansion.
